(19) United States
(12) Patent Application Publication
(10) Pub. No.: US 2006/0134931 A1
(43) Pub. Date: Jun. 22, 2006

(54) Method for forming quantum dots

(75) Inventor: Mong-Tung Lin, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Cheng City (TW)

(21) Appl. No.: 11/303,269

(22) Filed: Dec. 16, 2005

(30) Foreign Application Priority Data
Dec. 21, 2004 (TW) 93139761

(51) Int. Cl. H01L 21/00

(52) U.S. Cl. 438/800

(57) ABSTRACT

A method for forming quantum dots includes the following steps: (a) depositing a metal layer (4) on a substrate (2); (b) using an atomic force microscope (AFM) probe (6) to form a plurality of nanopores (42) in the metal layer (4); (c) depositing a semiconductor layer (3) on the metal layer and in the nanopores; and (d) removing the metal layer and the portions of the semiconductor layer located on the metal layer, thereby forming a plurality of quantum dots (82) on the substrate. The method does not use a photolithography technique, thus reduces or even avoids the possibility of forming various surface states. Furthermore, a potential effect of the thermal expansion coefficient of the metal is finite over the temperature range involved and thus the size of the nanopores, which are restricted by the metal layer, is essentially constant. Therefore, a size of the quantum dots is controllable.

### BACKGROUND

1. Field of the Invention

This invention relates generally to methods for manufacturing semiconductor devices and, more specifically, to a method for forming quantum dots.

2. Discussion of Related Art

Quantum dots are effectively zero-dimensional quantum structures. A quantum dot has a typical size of about 10 nanometers. The extreme sizes of quantum dots results in unique physical and optical properties from that of macro-materials. For example, the color of quantum dot can be easily tuned to different wavelength by simply changing the size of the dots. The principle behind this unique property is the quantum confinement effect. Thus, quantum dots are one of the most promising candidates for future high performance devices in communication systems, biomedical fields, sensors, detectors, and optical systems.

Conventional techniques for forming quantum dots are based on quantum well structures. One of those methods includes the following steps: forming a diffraction image on a surface of a substrate by passing a de Broglie wave (one of an electron beam, X ray, a neutron beam and a proton beam) through a thin crystal membrane while exposing the substrate to the etching gas; and using the energy of the de Broglie wave to selectively etch the substrate in accordance with the diffraction strength distribution of the de Broglie wave, which occurs at predetermined portions of the substrate. This method uses a photolithography technique, and this procedure is apt to produce a lot of surface states. The surface states are sources of non-radiative recombination centers, and presence of such centers would lower the optical quality of the quantum dots.

In order to reduce or even avoid the surface states, another conventional method for forming quantum dots incorporates the following steps: forming a quantum well layer on a substrate; forming a masking layer on the quantum well layer to produce a plurality of dot-shaped mask regions, which protect the underlying portions of the quantum well layer; using thermal etching to evaporate portions of the quantum well layer that are not protected by the dot-shaped mask regions of the masking layer so as to form a plurality of quantum dots; and forming on the quantum dots a layer of material having an energy gap that is greater than the energy gap of the quantum well layer.

The above-described method does not use the photolithography technique, thereby reducing or even avoiding the surface states. However, the thermal etching technique can not have a precise control on the quantum dot sizes, which infers complicate physical and optical properties.

What is needed, therefore, is a method which can reduce or even avoid a lot of surface states and form quantum dots with a controllable size.

### SUMMARY

In one embodiment, a method for forming quantum dots includes the following steps: (a) depositing a metal layer on a substrate; (b) using an atomic force microscope (AFM) probe to form a plurality of nanopores in the metal layer; (c) depositing a semiconductor layer on the metal layer and in the nanopores; and (d) removing the metal layer and the portions of the semiconductor layer located on the metal layer, thereby forming a plurality of quantum dots on the substrate.

In step (a), the substrate is made of a semiconductor material, such as silicon, germanium, gallium arsenide, indium gallium nitride, gallium nitride, indium nitride, and so on. The metal layer can be, for example, a gold layer, an aluminum layer, or a copper layer (i.e., beneficially a high-conductivity, oxidation-resistant metal layer). The AFM probe can, advantageously, be a silicon, silicon nitride, or carbon nanotube (CNT) probe. The semiconductor layer can be, for example, a silicon layer, a germanium layer, a gallium arsenide layer, an indium gallium nitride layer, a gallium nitride layer, or an indium nitride layer.

Compared with the conventional methods, the present method does not use a photolithography technique thus reduces or even avoids the possibility of forming various surface states. Furthermore, a potential effect of the thermal expansion coefficient of the metal is finite over the temperature range involved and thus the size of the nanopores, which are restricted by the metal layer, is essentially constant. Even if some expansion were to occur, the quantity can be calculated and controlled as an engineering parameter. In other words, the size of the quantum dots will be controllable. Furthermore, the sizes of the quantum dots can be varied by adopting AFM probes of different sizes. Therefore, the quantum dots formed by the present method will be able to provide the desired physical and optical properties.

Other advantages and novel features of the present method will become more apparent from the following detailed description of preferred embodiments with the accompanying drawings.

### BRIEF DESCRIPTION OF THE DRAWINGS

Many aspects of the present method can be better understood with reference to the following drawings. The components in the drawings are not necessarily to scale, the emphasis instead being placed upon clearly illustrating the principles of the present method.

FIG. 1 is a schematic, side elevation view of a substrate having a metal layer deposited thereon, according to the present method;

FIG. 2 is similar to FIG. 1, but showing a plurality of nanopores formed in the metal layer by an atomic force microscope (AFM) probe;

FIG. 3 is similar to FIG. 2, but showing a semiconductor layer deposited on the metal layer and in the nanopores; and

FIG. 4 is similar to FIG. 3, but showing the metal layer and the portions of the semiconductor layer located on the metal layer removed, thereby forming a plurality of quantum dots on the substrate.

Corresponding reference characters indicate corresponding parts throughout the several views. The exemplifications set out herein illustrate at least one preferred embodiment of the present method, in one form, and such exemplifications are not to be construed as limiting the scope of the present method in any manner.

### DETAILED DESCRIPTION OF PREFERRED EMBODIMENTS

Reference will now be made to the drawings to describe embodiments of the present method, in detail.

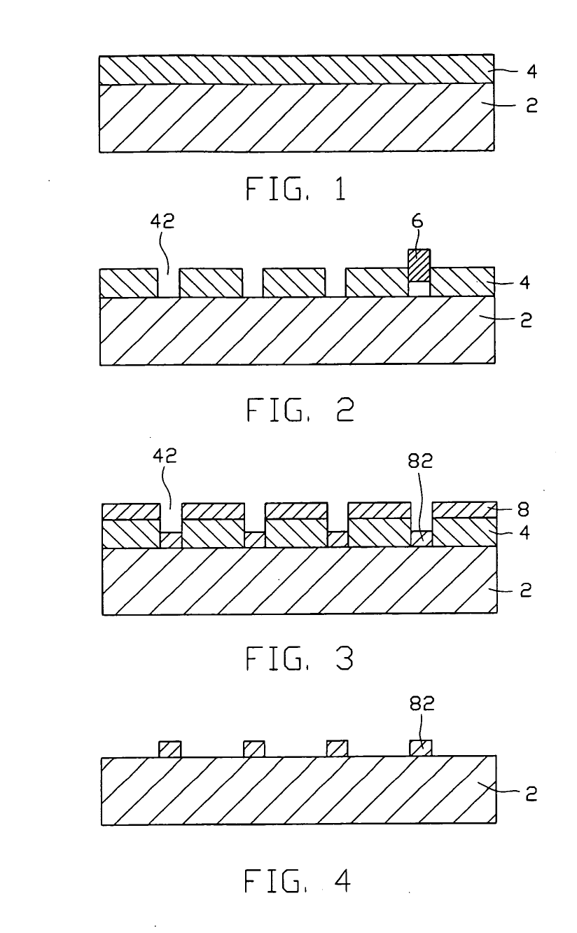

Referring to FIGS. 1, 2, 3 and 4, a method for forming quantum dots includes the following steps: (a) depositing a metal layer 4 on a substrate 2; (b) using an atomic force microscope (AFM) probe 6 to form a plurality of nanopores 42 in the metal layer 4; (c) depositing a semiconductor layer 8 on the metal layer 4 and in the nanopores 42; and (d) removing the metal layer 4 and the portions of the semiconductor layer 8 located on the metal layer 4, thereby forming a plurality of quantum dots 82 on the substrate 2.

Referring to FIG. 1, in step (a), the substrate 2 is made of semiconductor material, such as silicon, germanium, gallium arsenide, indium gallium nitride, gallium nitride, indium nitride, and so on. In the preferred embodiment, the substrate 2 is made of silicon. The metal layer 4 has finite thermal expansion coefficient and can, advantageously, be a gold layer, an aluminum layer, or a copper layer. In the preferred embodiment, the metal layer 4 is a gold layer. A thickness of the gold layer 4 is less than a height of the AFM probe 6. The gold layer 4 is deposited on the silicon substrate 2 by the following steps. Firstly, argon gas is fed into a high-vacuumed chamber and is ionized into a high-energy ion flow by a strong electric field. Secondly, the high-energy ion flow bombards a gold target, and this bombardment results in gold molecules sputtering on the silicon substrate 2 at high speed, thereby forming the gold layer 4.

Referring to FIG. 2, in step (b), the AFM probe 6 has a high mechanical intensity and a large aspect ratio. The AFM probe 6 can, e.g., be a silicon probe or a silicon nitride probe, and a size of the nanopores 42 formed thereby would be in the range from 20 nanometers to 40 nanometers. Furthermore, the AFM probe 6 can instead be a carbon nanotube probe, and a size of the nanopores 42 formed thereby would be in the range from 2 nanometers to 20 nanometers.

Referring to FIG. 3, in step (c), firstly, the silicon substrate 2, with the gold layer 4 having nanopores 42 formed therein, is placed in a vacuum chamber (not shown). Secondly, a second layer 8 is deposited on the metal layer 4 and in the nanopores 42, beneficially, by means of metal organic chemical vapor deposition (MOCVD). The second layer 8 can be, e.g., a silicon layer, a germanium layer, a gallium arsenide layer, an indium gallium nitride layer, a gallium nitride layer, or an indium nitride layer. In the preferred embodiment, the second layer 8 is a gallium nitride layer. During the MOCVD process, a temperature in the vacuum chamber is controlled at about 500-600° C. A thickness of the gallium nitride layer 8 can be controlled, by controlling the deposition time, as well as the deposition temperature.

Referring to FIG. 4, in step (d), the gold layer 4 and the portions of the gallium nitride layer 8 located on the gold layer 4 are removed by means of etching, according to standard semiconductor processes. Therefore, a plurality of quantum dots 82 is formed on the gold substrate 2.

Furthermore, the nanopores 42 with different sizes can be selectively formed by adopting the AFM probe 6 with different diameters in step (b). The size of such nanopores 42 will determine the size of the quantum dots 82. Therefore, quantum dots 82 with different sizes can be formed on the silicon substrate 2 in step (d).

Compared with a conventional dot formation procedure, the present method does not use a photolithography technique thus reduces or even avoids the possibility of forming various surface states. Furthermore, a potential effect of the thermal expansion coefficient of the gold is finite over the temperature range involved and thus the size of the nanopores 42, which are restricted by the gold layer 4, is substantially changeless or at least quite limited. A size of the quantum dots 82 is determined by that of the nanopores 42. Therefore, a size of the quantum dots 82 is controllable. Still furthermore, the size of the quantum dots 82 can be selectively varied by adopting AFM probes 6 of different sizes. Therefore, the quantum dots 82 formed by the present method will be able to provide the desired physical and optical properties.

Finally, it is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

We claim:

1. A method for forming quantum dots, comprising the steps:
(a) depositing a metal layer on a substrate;
(b) using an atomic force microscope (AFM) probe to form at least one nanopore in the metal layer;
(c) depositing a second layer on the metal layer and in the nanopore; and
(d) removing the metal layer and the portion of the second layer located on the metal layer, thereby forming at least one quantum dot on the substrate.

2. The method as claimed in claim 1, wherein the substrate in step (a) is made of a semiconductor material.

3. The method as claimed in claim 2, wherein the semiconductor material is at least one of silicon, germanium, gallium arsenide, indium gallium nitride, gallium nitride, and indium nitride.

4. The method as claimed in claim 1, wherein the metal layer in step (a) is at least one of a gold layer, an aluminum layer, and a copper layer.

5. The method as claimed in claim 1, wherein in step (a), the metal layer is deposited on the substrate by means of sputtering.

6. The method as claimed in claim 1, wherein the atomic force microscope (AFM) probe in step (b) is at least one of a silicon probe and a silicon nitride probe.

7. The method as claimed in claim 6, wherein a size of the quantum dot is in the approximate range from 20 nanometers to 40 nanometers.

8. The method as claimed in claim 1, wherein the atomic force microscope (AFM) probe in step (b) is a carbon nanotube (CNT) probe.

9. The method as claimed in claim 8, wherein a size of the quantum dot is approximately in the range from 2 nanometers to 20 nanometers.

10. The method as claimed in claim 1, wherein the second layer in step (c) is a semiconductor layer.

11. The method as claimed in claim 10, wherein the semiconductor layer is at least one of a silicon layer, a germanium layer, a gallium arsenide layer, an indium gallium nitride layer, a gallium nitride layer, and an indium nitride layer.

12. The method as claimed in claim 10, wherein in step (c), the second layer is deposited on the metal layer and in each nanopore by means of metal organic chemical vapor deposition (MOCVD).

13. The method as claimed in claim 1, wherein in step (d), the metal layer and the portion of the second layer located on the metal layer are removed by means of etching.
